(19) United States
(12) Patent Application Publication
(10) Pub. No.: US 2023/0102850 A1
(43) Pub. Date: Mar. 30, 2023

(54) RADIO PERMISSIVE IMPACT ABSORBING UNITARY COVER

(71) Applicant: Banner Engineering Corp., Minneapolis, MN (US)

(72) Inventors: Charles Dolezalek, Blaine, MN (US); Tim Hazelton, Plymouth, MN (US); Matthew Munn, Minneapolis, MN (US)

(73) Assignee: Banner Engineering Corp., Minneapolis, MN (US)

(21) Appl. No.: 17/935,763

(22) Filed: Sep. 27, 2022

Related U.S. Application Data
(60) Provisional application No. 63/261,693, filed on Sep. 27, 2021.

(51) Int. Cl. H05K 5/02; H05K 5/03

(52) U.S. Cl. CPC H05K 5/0217; H05K 5/03

(57) ABSTRACT

Apparatus and associated methods relate to a stretchable cover assembly permeable to electromagnetic signals formed within an enclosed device envelope to increase the resilience of the actuator body envelope against high-pressure fluid. In an illustrative example, a cover assembly is configured to encapsulate an electronic device. For example, the cover assembly may include a unitary envelope formed from a translucent, radio permissive, and ultraviolet light reflective material. An internal cavity defined by the unitary envelope may repeatedly receive substantially an entire exposed surface of the electronic device. The cover assembly may include an elastic opening that, in a relaxed state, the elastic opening is configured to be sealingly pressed against the enclosed electronic device forming a seal around the entire elastic opening to form a dust-tight and watertight cover. Various embodiments may advantageously protect the enclosed electronic device while selectively permitting electromagnetic signals to pass through.

### CROSS-REFERENCE TO RELATED APPLICATIONS

This application claims the benefit of U.S. Provisional Application Ser. No. 63/261,693, titled “Radio Permissive Impact Absorbing Unitary Cover,” filed by Charles Dolezalek, et al., on Sep. 27, 2021.

This application incorporates the entire contents of the foregoing application(s) herein by reference.

The subject matter of this application may have common inventorship with and/or may be related to the subject matter of the following:
U.S. application Ser. No. 15/254,564, titled “IMPACT ABSORBING UNITARY COVER ASSEMBLY” and filed Sep. 1, 2016, by Dolezalek, et al., issued as U.S. Pat. No. 9,984,835 on May 29, 2018.

This application incorporates the entire contents of the foregoing application(s) herein by reference.

### TECHNICAL FIELD

Various embodiments relate generally to radio permissive protection covers.

### BACKGROUND

A cover may be used to protect, shelter, and/or guard an enclosed object against undesired threat. For example, a cover may be an overlay or outer layer placed on an object for protection. For example, a tablecloth may be used as a cover for a dining table during a meal to protect the table against grease and other contamination (e.g., wine). In some examples, a cover may conceal and/or obscure an object from outside. For example, a car cover may conceal a car. A user may use a car cover to protect a car from extreme weather when the user may, for example, be away from the car for an extended time. Sometimes, a cover may be used for easy cleaning. For example, a mattress cover may provide an easy way to clean comparing to cleaning a mattress when contaminated

### SUMMARY

Apparatus and associated methods relate to a stretchable cover assembly permeable to electromagnetic signals formed within an enclosed device envelope to increase the resilience of the actuator body envelope against high-pressure fluid. In an illustrative example, a cover assembly is configured to encapsulate an electronic device. For example, the cover assembly may include a unitary envelope formed from a translucent, radio permissive, and ultraviolet light reflective material. An internal cavity defined by the unitary envelope may repeatedly receive substantially an entire exposed surface of the electronic device. The cover assembly may include an elastic opening that, in a relaxed state, the elastic opening is configured to be sealingly pressed against the enclosed electronic device forming a seal around the entire elastic opening to form a dust-tight and watertight cover. Various embodiments may advantageously protect the enclosed electronic device while selectively permitting electromagnetic signals to pass through.

Various embodiments may achieve one or more advantages. For example, some embodiments may be directed to enhance a water resisting capability of the cover assembly. For example, some embodiments may be directed to enhance user experience and controllability. For example, some embodiments may be directed to system and methods to include light transmission and radio transmission in and out of the cover assembly. For example, some embodiments may be directed system and methods to include light transmission and a touch activated module for the enclosed device.

The details of various embodiments are set forth in the accompanying drawings and the description below. Other features and advantages will be apparent from the description and drawings, and from the claims.

### BRIEF DESCRIPTION OF THE DRAWINGS

FIG. 1A depicts a cross-section view of an exemplary cover assembly having an internal cavity for covering an electronic device.

FIG. 1B depicts a perspective view of the cover assembly disposed on the electronic device.

FIG. 1C depicts a cross-section view of the cover assembly disposed on the electronic device.

FIG. 2 depicts a side view of an exemplary cover assembly.

FIG. 3A and FIG. 3B depict a side cross-section view of an exemplary cover assembly.

FIG. 4 depicts a top cross-section view of an exemplary cover assembly.

FIG. 5 depicts a bottom view of an exemplary cover assembly.

FIG. 6 depicts a perspective view of an exemplary cover assembly.

FIG. 7 depicts an assembly of an emitter and removable translucent cover. An assembly includes a cover assembled around an emitter housing.

FIG. 8 depicts an exemplary system including a pressure resistant cover and a touch sensitive device.

FIG. 9A and FIG. 9B depict an exemplary top perspective view and an exemplary side view of an exemplary system including a translucent (pressure-resistant) unitary cover assembled over a light-emitting module.

FIG. 10A, FIG. 10B, FIG. 10C, and FIG. 10D depict an exemplary cover assembly in a second embodiment.

FIG. 11A and FIG. 11B depict a cross-section view of the cover assembly described with reference to FIGS. 10A-D.

FIG. 12 depicts a perspective view of an exemplary cover assembly disposed on an electronic device.

FIG. 13 depicts a cross-section view of the exemplary cover assembly of FIG. 12.

Like reference symbols in the various drawings indicate like elements.

### DETAILED DESCRIPTION OF ILLUSTRATIVE EMBODIMENTS

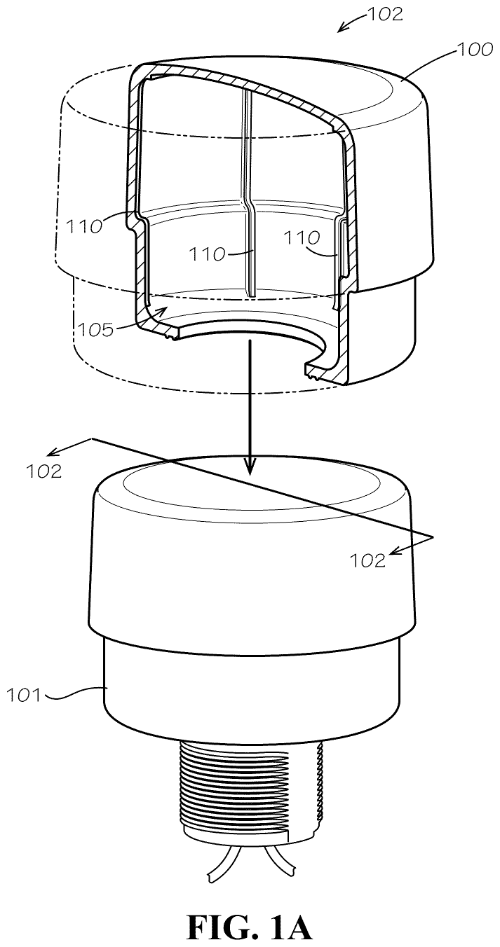

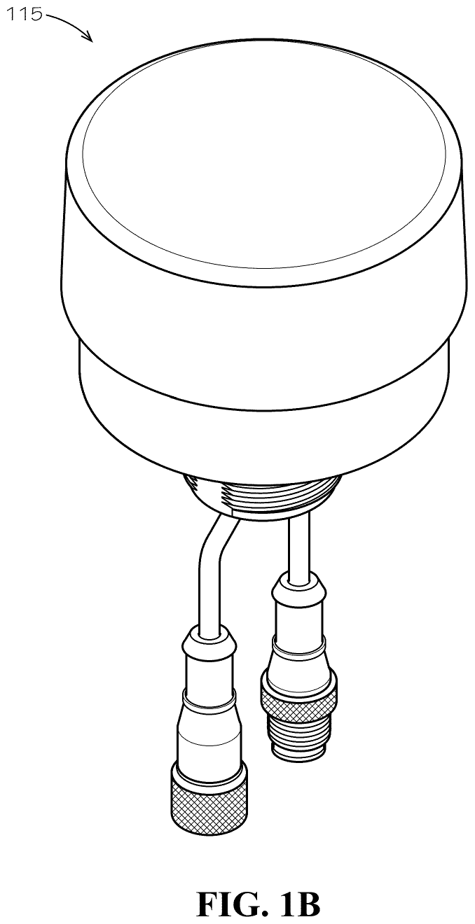

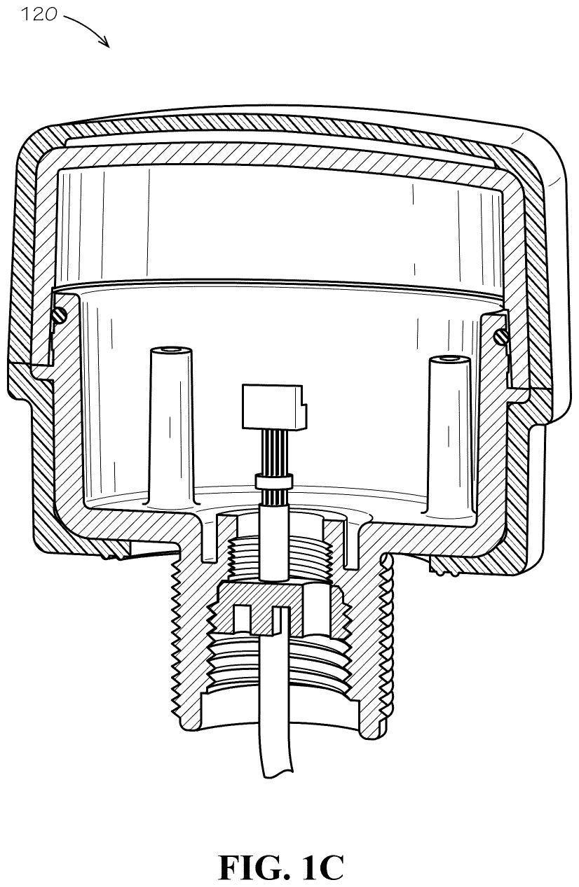

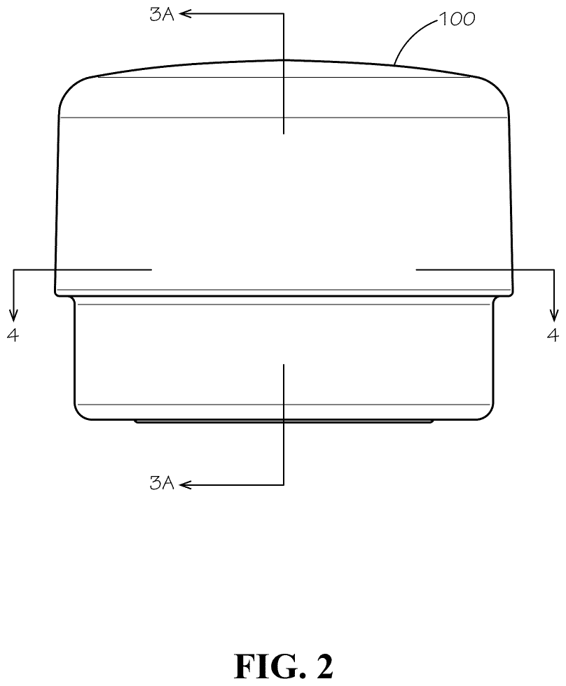

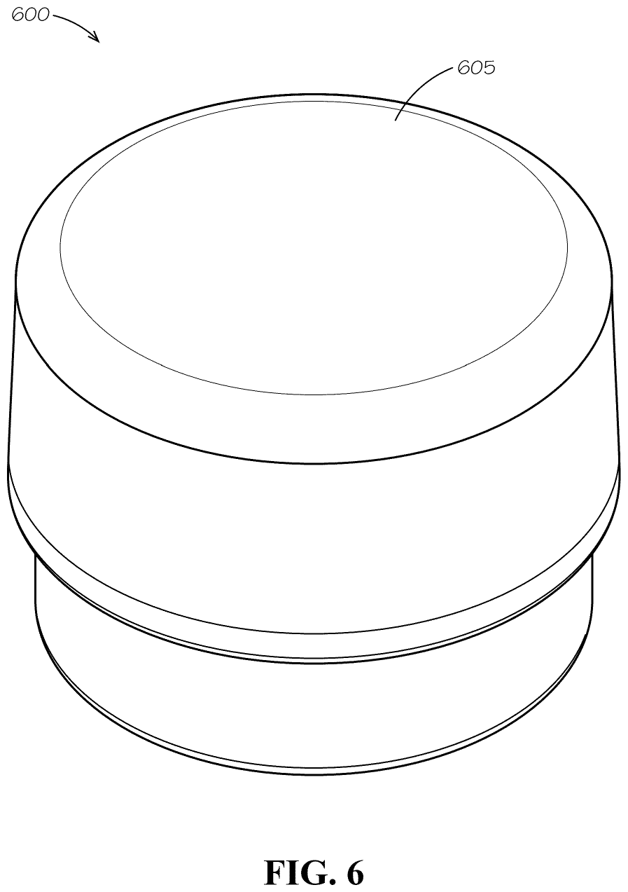

To aid understanding, this document is organized as follows. First, an exemplary cover assembly having ribs is briefly introduced with reference to FIG. 1. Second, with reference to FIGS. 2-5, the discussion turns to exemplary embodiments that illustrate a cover assembly having ribs. The ribs of the cover assembly may provide protection against high-pressure water cleanings while permitting radio waves to pass through. In some embodiments, the cover assembly may be repeatedly removable. Finally, with reference to FIGS. 6-11B, further embodiments of the exemplary cover assemblies are discussed.

FIG. 1A depicts a cross-section view 102 of an exemplary cover assembly configured to cover an electronic device. In the depicted example, a cover assembly 100 is configured to be (removably) disposed over an electronic device 101. For example, the electronic device 101 may be used in a car wash processing center. For example, the electronic device 101 may be used in a food processing plant. The electronic device 101, for example, may be a sensor (e.g., a temperature sensor, a light sensor, a touch capacitive sensor). The electronic device 101, for example, may be an indicator (e.g., a LED indicator, an electronic display). The electronic device 101, for example, may be a radio transmitter. The electronic device 101, for example, may be a radio receiver.

The cover assembly 100 is provided with an internal cavity 105 to receive the electronic device 101. In some embodiments, the cover assembly 100 may forma a continuous surface substantially enclosing the electronic device 101 in the internal cavity 105 to protect the electronic device 101. For example, the cover assembly 100 may protect the electronic device 101 against a high pressure and/or high temperature water used to clean an operating environment of the electronic device. As shown in FIG. 1, the cover assembly 100 includes ribs 110 extending (protruding) radially inward from an interior surface of the cover assembly 100. The ribs 110, as depicted, extend longitudinally along an interior surface of the cover assembly 100. In some implementations, the ribs 110 may permit the cover assembly 100 to cushion a high-pressure water as it contacts the cover assembly 100 to prevent damage (e.g., ripping, fraying, puncture) of the cover assembly 100. For example, the cover assembly 100 may protect an electronic device against high-pressure fluid up to at least 1100 pounds per square inch (psi). In some embodiments the cover assembly 100 may protect the electronic device 101 against high-pressure fluid up to at least 1450 pounds per inch.

In some implementations, the cover assembly 100 may be formed from a translucent amorphous material. For example, the cover assembly 100 may be formed from a translucent silicone. In various embodiments, the cover assembly 100 may be formed from a flexible material. The flexible material may allow the cover assembly 100 to expand to facilitate repeated installation and removal of the cover assembly 100 over an electronic device, such as a radio device, for example. As an illustrative example without limitations, the radio device may include a portable device that may include a replaceable battery unit. In some implementations, the cover assembly 100 may be formed from a flexible material to permit a user to repeatedly remove the cover assembly 100 for battery replacement and/or other maintenance events. For example, the user may re-install the cover assembly 100 over the electronic device after the maintenance event.

In some implementations, the cover assembly 100 may provide characteristics desired in an environment that requires sanitation using high temperature, high-pressure fluid, such as a cleaning solution or solvent, for example. In some implementations, the cover assembly 100 may provide characteristics desired in an unfavorable environment that may be damaging to the electronic device. The cover assembly 100 may protect the electronic device in an environment where flooding is frequent, for example. In some examples, a user may replace the cover assembly 100 in the event the cover assembly 100 becomes compromised.

In some implementations, the cover assembly 100 may be ultraviolet (UV) stabilized. For example, the cover assembly 100 may be made of UV stabilized silicone. The UV stabilized cover assembly 100, for example, may protect a plastic housing of the electronic device 101. In some examples, the cover assembly 100 may selectively reflect one or more ranges of electromagnetic waves. For example, the cover assembly 100 may reflect a UV spectrum of the radio wave while the cover assembly 100 may be permissive to an electromagnetic wave transmission radio frequency.

In some implementations, the cover assembly 100 may be food grade. For example, the cover assembly 100 may be non-toxic. For example, when the cover assembly 100 is being washed down in a food processing environment (e.g., with chemicals, pressure washing), food exposed directly and/or indirectly to the cover assembly 100 may be safe to be consumed. In various examples, the cover assembly 100 may include material having integrity will be upkept under high pressure (e.g., up to 1450 psi) and high temperature (e.g., >75° C.) sanitation and cleaning processes.

In some embodiments, the cover assembly 100 may be formed from a material permissive to electromagnetic waves. For example, the electronic device 101 may include a radio covered by the cover assembly 100. The radio may be operable to transmit and/or receive radio waves through the cover assembly 100. The cover assembly 100 may be formed from electromagnetically permissive material. For example, the material may be radio wave permissive. In some examples, the electromagnetically permissive material may be configured to have a carbon colorant no greater than a predetermined maximum threshold. The electromagnetically permissive material may, for example, be configured to have metallic content less than a predetermined maximum threshold. In some embodiments the electromagnetically permissive material may be configured such that an electromagnetic reflectivity is below a (predetermined) maximum threshold. In some embodiments the electromagnetically permissive material may, for example, be configured such that an electromagnetic absorptivity of the material is below a (predetermined) maximum threshold. The electromagnetically permissive material may, for example, be configured with a minimum (relative) permittivity for at least one frequency of interest. The frequency may, for example, be configured based on a target communication device (e.g., radio) to be covered (e.g., a predetermined frequency range of the radio).

In some examples, the electromagnetic permitting material may include silicone. In some implementations, the cover assembly 100 may be formed with translucent silicone with a durometer of substantially shore A50. In some embodiments the cover assembly 100 may be formed with translucent silicone with a durometer of substantially shore A40.

In various implementations, the cover assembly 100 may be a translucent, radio permissive, and ultraviolet light reflective cover defining an internal cavity (the internal cavity 105 in FIG. 1A). For example, the internal cavity may be configured to repeatedly receive substantially an entire exposed surface of an enclosed device (e.g., the electronic device 101). For example, the cover assembly 100 may include an elastic opening into the internal cavity. In a stretched state, for example, the elastic opening may increase in area to encapsulate the electronic device within the cover assembly 100. In a relaxed state, for example the area of the elastic opening may decrease smaller than at least one cross-sectional area of the enclosed electronic device. Accordingly, for example, the cover assembly 100 may be sealingly pressed against the enclosed electronic device around the entire elastic opening to form a dust-tight and watertight cover.

FIG. 1B depicts a perspective view 115 of the cover assembly 100 disposed on the electronic device 101. The cover assembly 100 may, for example, be (mechanically) sealed around the electronic device 101 when the electronic device 101 is (releasably) coupled to a mounting surface (e.g., by a threaded nut). FIG. 1C depicts a cross-section view 120 of the cover assembly 100 disposed on the electronic device 101.

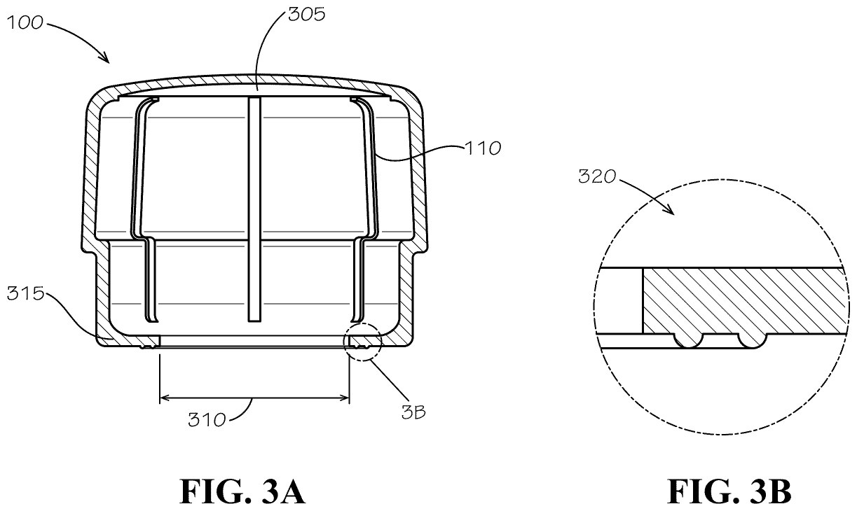

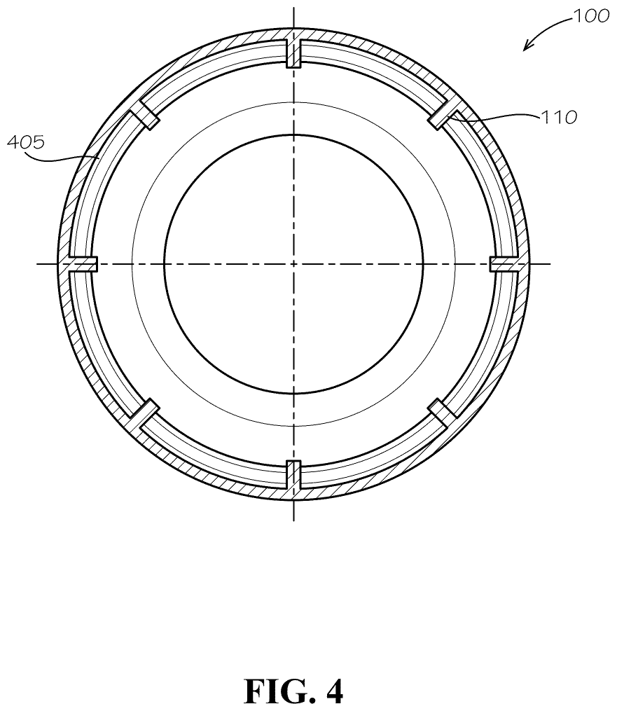

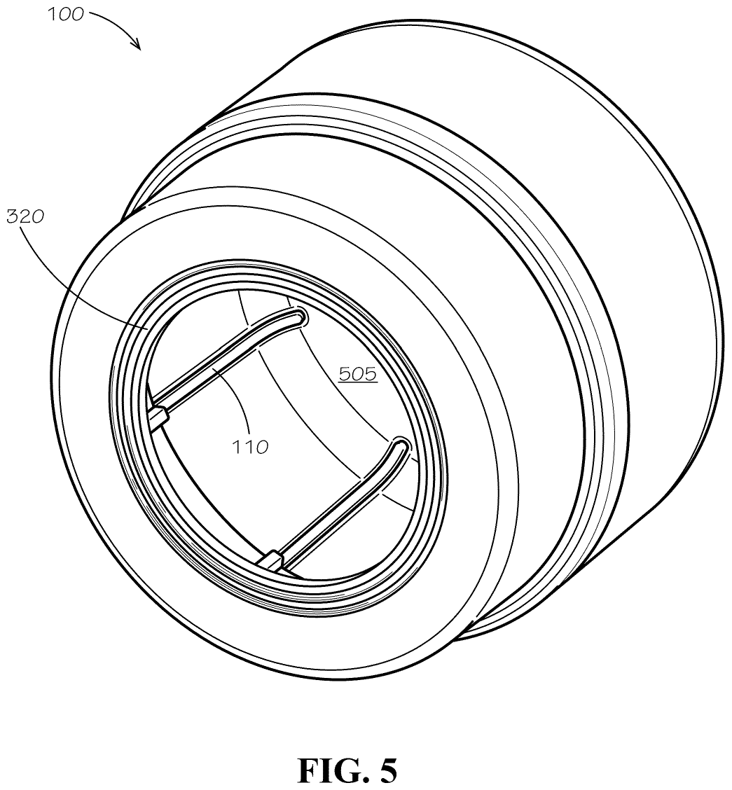

FIG. 2 depicts a side view of an exemplary cover assembly 100. Although one example shape and form of the cover assembly 100 is depicted, other shapes may be manufactured to fit an envelope of the covered electronic device. In this example, two cross-section views A-A and B-B are outlined. The cross-section view A-A is described with reference to FIG. 3, and the cross-section view B-B is described with reference to FIG. 4.

FIG. 3A and FIG. 3B depict a side cross-section view of an exemplary cover assembly 100. As shown in FIG. 3A, the cover assembly 100 includes a loose fit top portion 305 of the cover assembly 100. In some implementations, the loose fit top portion 305 may allow touch buttons of an enclosed device to be activated directly on the cover assembly 100. In some implementations, the cover assembly may be configured to allow electronic signals to pass through. For example, a user may activate a capacitive touch button of the enclosed device directly on the cover assembly 100. In some implementations, some of the ribs 110 (as shown in FIG. 1A) may be discontinuous, such that the sealing envelope may be displaced into contact with the touch buttons

At the bottom of the cover assembly 100, in this example, includes an insertion aperture 310 and a sealing envelope 315. A user may insert an electronic device, such as a radio, through the insertion aperture 310 into the internal cavity 105. In some examples, the inserted electronic device may include a proximal surface. In some implementations, when the electronic device is fully inserted into the internal cavity 105, the sealing envelope 315 may form a seal against the proximal surface of the electronic device. The seal may protect the electronic device against high-pressure fluid up to 1450 pounds per inch. The insertion aperture 310 may stretch such that the proximal surface of the electronic device to pass through the insertion aperture 310. For example, the insertion aperture 310 may have a 42 mm radius. To allow the electronic device passes through so that a user may peel off the cover assembly 100 at a distal end from the electronic device to pass through, the insertion aperture 310 may, for example, be stretchable to 76.25 mm in radius. In various embodiments, the cover assembly 100 may be made with material of a radial elongation of the insertion aperture 310 may be more than 40%. In some implementations, the cover assembly 100 may be made with material of a radial elongation of the insertion aperture 310 may be more than 85%. In some examples, a bigger radial elongation may advantageously improve sealing force at the insertion aperture 310.

The sealing envelope 315 includes raised rings 320 (as shown in a close-up diagram in FIG. 3B) on its exterior surface. The raised rings 320 may concentrate pressure when a device is secured in an environment to stop a high-pressure spray from entering the cover assembly 100.

FIG. 4 depicts a top cross-section view of an exemplary cover assembly 100. The top cross-section of the cover assembly 100 is from the section B-B of FIG. 2. In this example, the cover assembly 100 includes eight ribs 110. In some examples, other numbers (e.g., 6, 12, 16, etc.) of ribs may be used. In some embodiments, the ribs 110 may contact an enclosed electronic device to permit an air channel between the enclosed electronic device and a wall 405 of the cover assembly 100. As depicted, the ribs 110 are substantially equal distance from each other. In various embodiments, the ribs 110 may be of different distances from each other.

In various embodiments, the cover assembly 100 may include different shaped ribs 110. For example, the cover assembly 100 may include ribs in a cross-shaped pattern disposed throughout the cover assembly 100. In various embodiments, the enclosed electronic device may also include ribs. In some implementations, air channels or pockets created by the ribs 110 may facilitate the removal of the cover assembly 100 from the enclosed electronic device.

The dimensions disclosed at least with reference to FIGS. 2-5 are exemplary dimensions for illustrative purposes of at least one embodiment.

FIG. 5 depicts a bottom view of an exemplary cover assembly. The sealing envelope 315 of the cover assembly 100 partially extends to cover a portion of a proximal surface 505 of an enclosed device. In some examples, based on an elasticity of the cover assembly 100, the area of the proximal surface 505 covered by the sealing envelope 315 may be urged against an inner surface of the sealing envelope 315 to create a tight seal. The raised rings 320 may prevent exposure of potentially detrimental substances at the proximal surface 505 not covered by the sealing envelope 315. For example, the raised rings 320 may, when compressed between the enclosed device and a mounting surface, increase a pressure concentration substantially circumferentially around an aperture into the cavity of the cover assembly 100. Accordingly, a seal (e.g., liquid tight, fluid tight) may, for example, be advantageously created.

FIG. 6 depicts a perspective view of an exemplary cover assembly 600. For example, the cover assembly 600 may be configured to enclose a communication device capable of radio transmission. In some embodiments, the cover assembly 600 may enclose an electronic device with capacitive touch sensor for receiving user input.

A surface 605 of the cover assembly 600 may, in some embodiments, be translucent. For example, the enclosed communication device may transmit light signals in and out of the cover assembly 600. In some examples, the enclosed communication device may transmit radio signals in and out of the cover assembly 600. In some implementations, the enclosed device may include at least one LED indicator for communicating information to a user through the translucent surface. In some embodiments, the enclosed device may include a display, such as an LCD display, for displaying various information, images, and/or video to the user through the translucent surface. Materials of various hardness may be used to form the cover assembly 600. For example, the material may have a durometer of shore A 30-50.

Although various embodiments have been described with reference to the figures, other embodiments are possible. In some implementations, the cover assembly 100 may be configured to enclose a digital assistant capable of receiving voice command from a user, performing various tasks as requested by the user by accessing a data network, and generate output by generating a signal to other device via the data network and/or by generating a voice to inform the user. In some implementations, the cover assembly 100 may be configured to enclose a wireless speaker. For example, the wireless speaker may be activated via a touch-activated module to receive music signals through the electromagnetic wave permeable cover assembly and generate a sound wave.

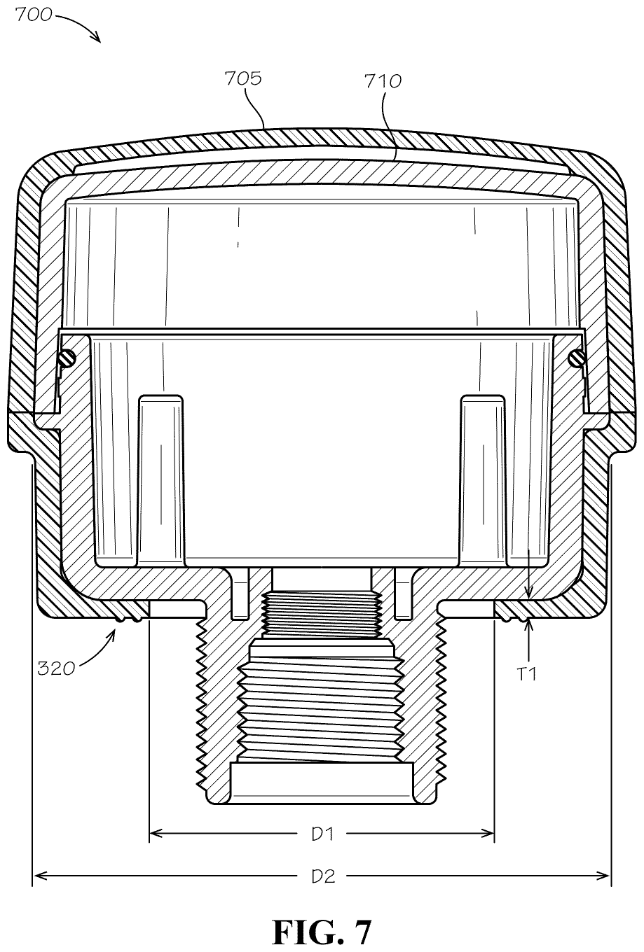

FIG. 7 depicts an assembly of an emitter and removable translucent cover. An assembly 700 includes a cover 705 assembled around an emitter housing 710. The emitter housing 710 may, for example, enclose an electromagnetic emitter (e.g., radio transceiver, not shown). The cover 705 may, for example, be permissive to radio signals such that the radio signals, for example, are not appreciable attenuated. For example, in some embodiments the cover 705 may be configured such that the radio signals are attenuated by less than 1%. The cover 705 may be configured such that the radio signals are attenuated by less than 5%. The cover 705 may be configured such that the radio signals are attenuated by less than 10%. The cover 705 may be configured such that the radio signals are attenuated by less than 15%. The cover 705 may be configured such that the radio signals are attenuated by less than 20%.

In the depicted example, the cover 705 is provided with an aperture having a diameter D1. A maximum diameter of the emitter housing 710 is D2. The cover 705 may be configured such that the aperture may be temporarily enlarged at least by (D2−D1)=D3 such that the cover 705 may be fitted over and/or removed from the emitter housing 710.

The cover 705 may be configured such that a maximum force is required to operate the aperture from D1 to D2. In some embodiments the cover 705 may be configured such that a maximum force is required to operate the aperture from D1 to D2+x=D4, where x is a dimension (e.g., less than D1) configured to allow a clearance fit over the emitter housing 710.

In some embodiments the cover 705 may be configured such that a minimum force is required to operate the aperture from D1 to D2. For example, the cover 705 may be configured such that a minimum force may be required to expand the aperture at D1. For example, various embodiments may be configured to resist accidental unsealing of the cover 705 from around the emitter housing 710 and/or accidental slippage of the cover 705 off of the emitter housing 710.

In some embodiments, the cover 705 may be configured such that the material's percent elongation within an elastic range includes an elongation required to operate the aperture to D2 and/or D4. For example, D2/D1 may be within an elastic region of the material. In some embodiments D4/D1 may, for example, be within an elastic region of the material.

In some embodiments the elasticity and/or force may be at least partially determined by a thickness T1 of the cover 705 at the aperture. T1 may, for example, be less than D1. A force of operation may, for example, be substantially proportional to T1.

In relation to some embodiments, FIG. 7 may be drawn to scale, at least with reference to (D2−D1):T1.

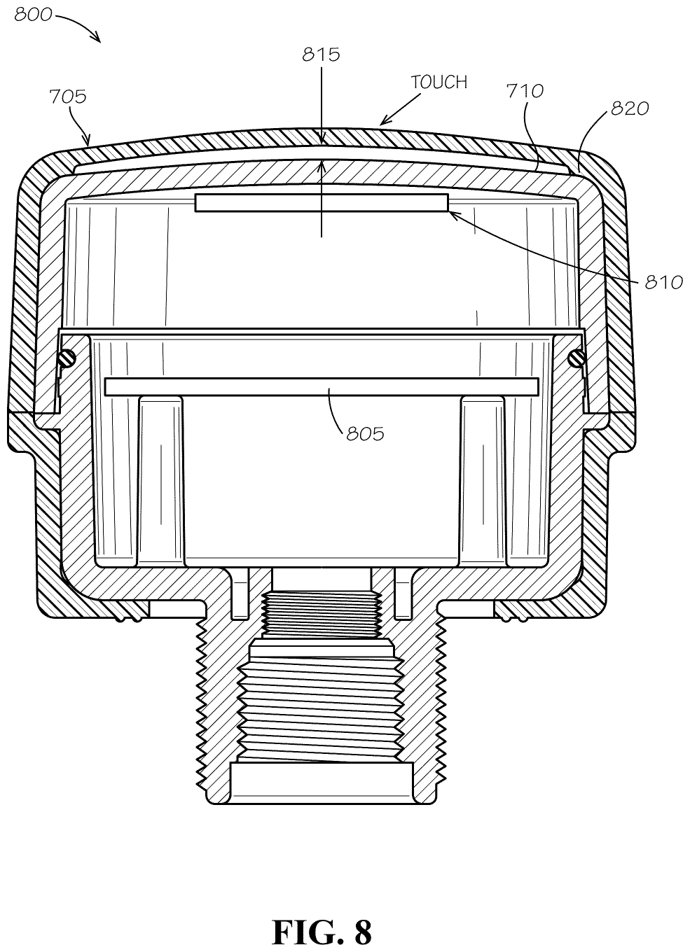

FIG. 8 depicts an exemplary system including a pressure resistant cover and a touch sensitive device. A system 800 includes the cover 705 disposed over the emitter housing 710. The emitter housing 710, as depicted, includes an emitter circuit 805. The emitter circuit 805 may be operably coupled to a touch-sensitive circuit 810. The touch-sensitive circuit 810 may, for example, include a capacitive electrode. The emitter circuit 805 may, for example, operate in response to input signals generated by the touch-sensitive circuit 810 in response to touch input from a user(s).

In the depicted example, the cover 705 is separated, at least at a top surface, from the emitter housing 710 by an air gap 815. The air gap 815 may, for example, be provided by ribs 820 having a thickness such that a surface of the cover 705 is separated from a touch-sensitive surface of the emitter housing 710 by the air gap 815.

The cover 705 may, for example, be configured such that touch input (e.g., of at least a (predetermined) minimum force and/or displacement) may induce (local) deformation of the cover 705 such that the air gap is closed. The cover 705 may, for example, be configured such that the touch-sensitive circuit 810 responds to touch through the cover 705. In some embodiments the cover 705 may be configured such that the touch-sensitive circuit 810 responds to contact with the cover 705. In some embodiments, a sensitivity setting touch-sensitive circuit 810 may be configured to determine a predetermined minimum touch force. The ribs 820 may, for example, be configured to determine a predetermined minimum displacement.

In some embodiments the air gap 815 may, for example, be configured such that the cover 705 and/or the enclosed device may withstand a high-pressure spray (e.g., at least up to a predetermined pressure level). For example, the air gap 815 may be configured such that the cover 705 deflects upon impact by a high-pressure fluid stream such that an energy unit per unit time is decreased as experience per unit of the material (e.g., mass, volume). Various such embodiments may, for example, advantageously reduce or eliminate destruction and/or damage to the cover 705 by a high-pressure stream (e.g., pressure washing).

In some embodiments the air gap 815 may be configured such that an amount of force is required to close the gap (e.g., to urge the cover 705 into contact with the touch-sensitive surface(s)). For example, a (predetermined) minimum amount of force may be required to cause the cover 705 to deflect and contact the touch-sensitive surface. The touch-sensitive circuit 810 may, for example, be configured to actuate upon a contact event corresponding to the (predetermined) minimum amount of force. For example, the touch-sensitive circuit 810 may be configured to actuate only upon application of at least the (predetermined) minimum amount of force.

Various such embodiments may, for example, advantageously reduce false actuation. Some embodiments may, for example, advantageously reduce false actuations due to fluid (e.g., water, such as condensation) collected on the surface of the touch-sensitive circuit 810 and/or an external surface of the cover 705. For example, water leftover from washing may be on the external surface of the cover 705. The minimum force required to close the air gap 815 may, for example, prevent the water on the cover 705 from closing the air gap 815 and actuating the touch-sensitive circuit 810. The minimum force may, for example, prevent foreign material (e.g., dust, oil, debris) on the cover 705 from closing the air gap 815 and actuating the touch-sensitive circuit 810.

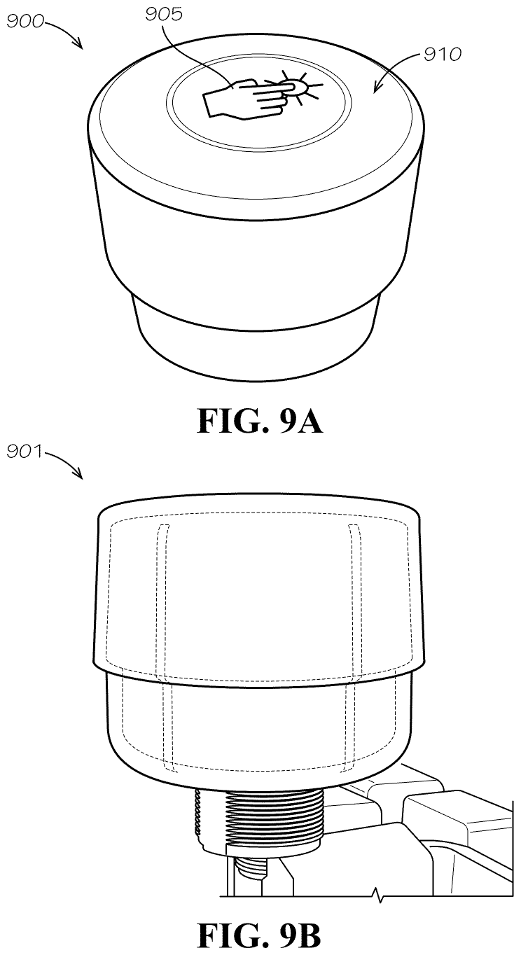

FIG. 9A and FIG. 9B depict an exemplary top perspective view 900 and an exemplary side view 901 of an exemplary system including a translucent (pressure-resistant) unitary cover assembled over a light-emitting module. The light-emitting module may, for example, include a radio transceiver. The unitary cover may, for example, be electromagnetically permissive (e.g., optical and/or radio permissive).

As shown in FIG. 9A, the light-emitting module includes a capacitive touch sensor 905 as shown through a translucent top surface 910. For example, a user may activate the capacitive touch sensor 905 by touching against the translucent top surface 910.

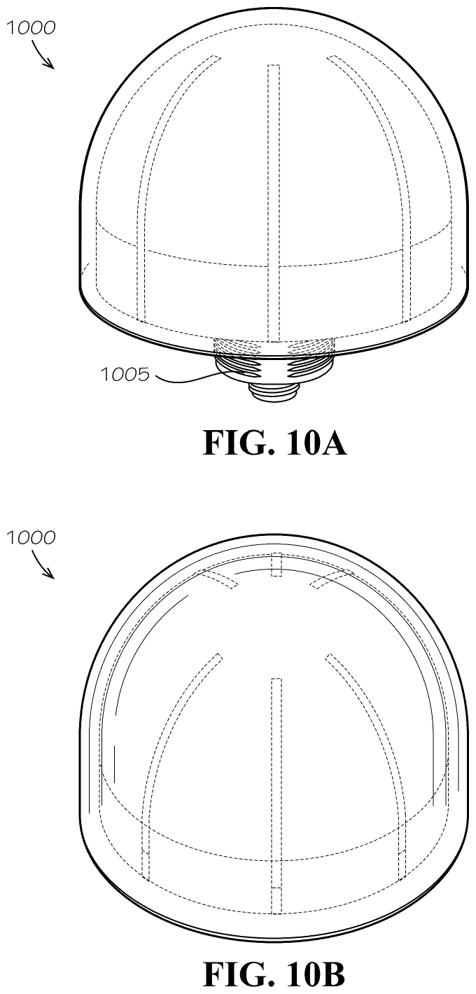

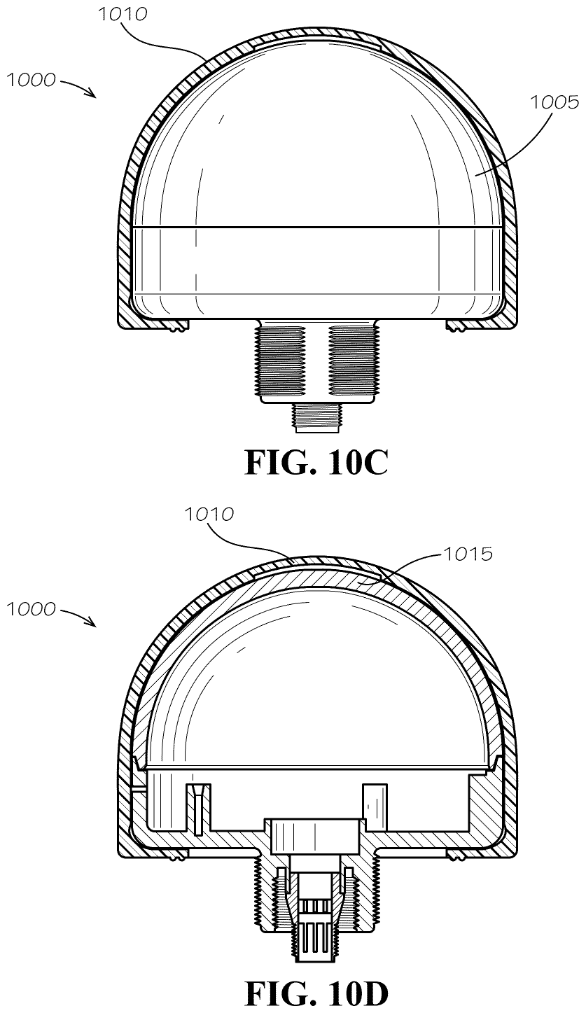

FIG. 10A, FIG. 10B, FIG. 10, and FIG. 10D depict an exemplary cover assembly 1000 in a second embodiment. As shown in FIG. 10A, the cover assembly 1000 may encapsulate a dome light 1005. As shown in FIG. 10C, the cover assembly 100 may form a sealing envelope 1010 around substantially entirely of the dome light 1005. For example, the sealing envelope 1010 may protect the dome light 1005 against high pressure water and dust while emitted light 1015 (FIG. 10D) from the dome light 1005 is permitted to pass through.

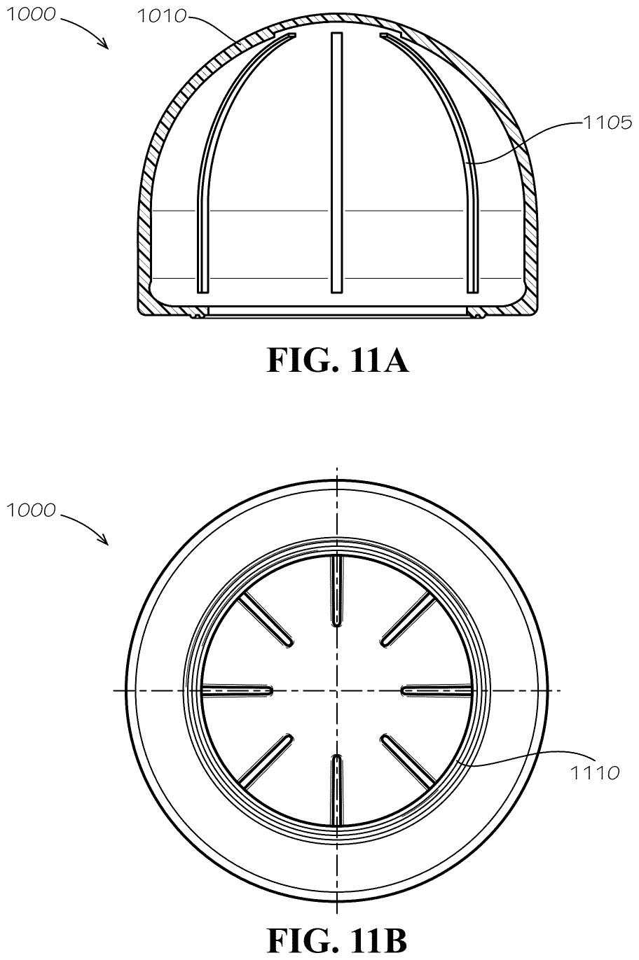

FIG. 11A and FIG. 11B depict a cross-section view of the cover assembly described with reference to FIGS. 10A-D. As shown in FIG. 11A, the cover assembly 1000 includes ribs 1105. For example, the ribs 1105 may permit the cover assembly 1000 to cushion a high-pressure water as it contacts the cover assembly 1000 to prevent damage (e.g., ripping, fraying, puncture). As shown in FIG. 11B, raised rings 1110 may concentrate pressure when an enclosed device (e.g., the dome light 1005) is secured in an environment to stop a high-pressure spray from entering the cover assembly 1000.

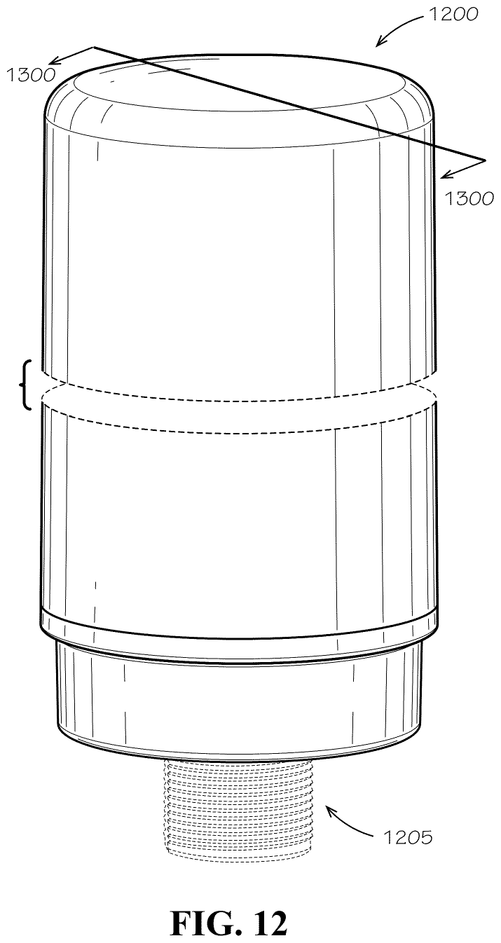

FIG. 12 depicts a perspective view of an exemplary cover assembly disposed on an electronic device. In the depicted example, a unitary cover 1200 is disposed over an electronic device 1205 of extended height (height removed for clearer reproduction, as indicated by interrupted dashed lines and bracket)

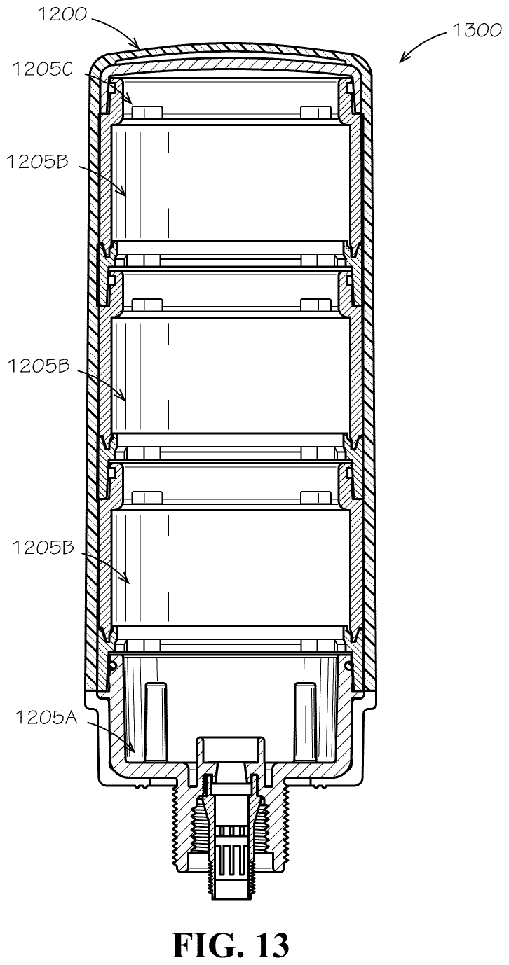

FIG. 13 depicts a cross-section view 1300 of the exemplary cover assembly of FIG. 12. The unitary cover 1200 is disposed over the electronic device 1205. For example, an aperture of the unitary cover 1200 may be stretched to a sufficient diameter to place the unitary cover 1200 over the electronic device 1205. Once released, the aperture may substantially (e.g., with negligible change in unstretched diameter before and after stretching, such as <5%, <2%, <1%) return to its unstretched diameter. The electronic device 1205 may be secured (e.g., by a nut and/or washer) threaded onto a stem (as shown projecting downward through the aperture of the unitary cover 1200 in FIGS. 12-13) such that a perimeter of the aperture of the unitary cover 1200 is sealingly coupled to the electronic device 1205.

As shown in the depicted example, the electronic device 1205 may include a multi-section device. The illustrative example shown includes a base section 1205A, and multiple additional sections 1205B. As depicted, the electronic device 1205 includes an uppermost section 1205C. The sections may, by way of example and not limitation, include lights and/or other visual displays. The sections may, for example, include emitters and/or receivers (e.g., a radio unit transceiver). The sections may, for example, include inputs (e.g., buttons, touch inputs, such as the uppermost section 1205C). The sections may, for example, include audio units (e.g., buzzers, sirens, alarms, speakers).

Some embodiments of the unitary cover may, for example, be configured for a predetermined section configuration (e.g., 5 sections, 4 sections, 2 sections, a predetermined height). Accordingly, a premanufactured unitary cover may, for example, advantageously be applied to a custom-configured tower unit (e.g., tower light) using modular sections.

In some embodiments, a cover assembly may be made of multiple unitary cover sections. For example, multiple sections may interlock on corresponding edges. A lower section and a top section may interlock. Intermediate sections may interlock on upper and lower edges. A stack of cover sections may be assembled by interlocking (e.g., interlocking ridge and groove) together to form a single cover assembly. The sections of the cover assembly may, for example, sealingly couple to form a continuous fluid-resistant cover. Some examples may use fasteners (e.g., one or more ring clamps) to couple the sections.

In some examples, the sections of the cover assembly may permanently couple. For example, sections may be welded (e.g., solvent welding, UV welding, heat welding). In some examples, sections may be adhered together (e.g., adhesive, epoxy).

Although an exemplary system has been described with reference to FIGS. 1-5, other implementations may be deployed in other industrial, scientific, medical, commercial, and/or residential applications. For example, the cover assembly 100 may be custom fit to substantially protect against dust. The cover assembly 100 may resist ingress of high temperature (e.g., steam), high pressure cleaning such as 80-degree Celsius water sprayed at approximately 1160-1450 pounds per square inch (psi), for example. The cover assembly may resist ingress of water at a flow rate up to 16 liters per minute. As such, the cover assembly 100 may obtain a rating of IP69K for use in applications requiring high-pressure, high temperature washdown to sanitize equipment.

In an illustrative aspect, a water resistant and ultraviolet light stabilized electronic system may include an electronic device and a cover assembly configured to encapsulate the electronic device. The cover assembly may include an unitary envelope formed from a translucent, radio permissive, and ultraviolet light reflective material. For example, the unitary envelope may define an internal cavity configured to repeatedly receive substantially an entire exposed surface of the electronic device.

The ultraviolet light stabilized electronic system may include an insertion aperture, at a distal end of the unitary envelope. The insertion aperture may define an elastic opening into the internal cavity. The elastic opening may define a cross-sectional area of a fluid communication channel into the internal cavity. For example, in a stretched state, the cross-sectional area may increase to encapsulate the electronic device within the cover assembly. In a relaxed state, the cross-sectional area may decrease to an area smaller than at least one cross-sectional area of the encapsulated electronic device such that the elastic opening is configured to be sealingly pressed against the encapsulated electronic device forming a seal around the entire elastic opening to form a dust-tight and watertight cover

For example, the encapsulated electronic device may be configured to operate normally against an ingress of water up to a pressure of 1450 pounds per square inch, and up to a temperature of 80° C.

In an illustrative aspect, a cover assembly for an electronic device may include a unitary envelope formed from a translucent, radio permissive, and ultraviolet light reflective material. For example, the unitary envelope defines an internal cavity may be configured to repeatedly receive substantially an entire exposed surface of an enclosed electronic device. The cover assembly may include a plurality of inwardly protruding members configured to separate a continuous surface of the internal cavity from the exposed surface of the enclosed electronic device. The cover assembly may include an insertion aperture, at a distal end of the unitary envelope, defines an elastic opening into the internal cavity. The elastic opening may define a cross-sectional area of a fluid communication channel into the internal cavity. In a stretched state, the cross-sectional area may increase to encapsulate the enclosed electronic device within the cover assembly. In a relaxed state, the cross-sectional area may decrease to an area smaller than at least one cross-sectional area of the enclosed device. For example, the elastic opening may be configured to be sealingly pressed against the enclosed electronic device forming a seal around the entire elastic opening to form a dust-tight and watertight cover.

For example, when the enclosed electronic device is encapsulated within the unitary envelope, over a predetermined touch input region of the enclosed electronic device, at least one of the plurality of inwardly protruding members may be configured to be discontinuous. The unitary envelope may be configured to be displaced into contact with the touch input region in response to a touch input.

For example, when the enclosed electronic device is encapsulated within the unitary envelope, the plurality of inwardly protruding members longitudinally may extend from the distal end of the internal cavity towards a proximal surface of the enclosed electronic device, such that a resilience of the unitary envelope against a high-pressure fluid is increased.

For example, the insertion aperture may be configured to elongate radially by up to 80% to receive the electronic device. For example, the translucent, radio permissive, and ultraviolet light reflective material may include food-grade silicone.

For example, the translucent, radio permissive, and ultraviolet light reflective material may include a translucent amorphous material. For example, the seal may provide protection against an ingress of water up to a pressure of 1450 pounds per square inch, and up to a temperature of 80° C. For example, the enclosed electronic device may be a LED indicator. For example, the enclosed electronic device may be a capacitive touch input sensor. For example, the enclosed electronic device may be a radio transceiver.

In an illustrative aspect, a cover assembly for an electronic device may include a unitary envelope formed from a translucent, radio permissive, and ultraviolet light reflective material. The unitary envelope may define an internal cavity configured to repeatedly receive substantially an entire exposed surface of an enclosed electronic device. The cover assembly may include an in insertion aperture, at a distal end of the unitary envelope, defines an elastic opening into the internal cavity, wherein the elastic opening defines a cross-sectional area of a fluid communication channel into the internal cavity. In a stretched state, the cross-sectional area may increase to encapsulate the enclosed electronic device within the cover assembly. In a relaxed state, the cross-sectional area may decrease to an area smaller than at least one cross-sectional area of the enclosed electronic device such that the elastic opening may be configured to be sealingly pressed against the enclosed electronic device forming a seal around the entire elastic opening to form a dust-tight and watertight cover.

For example, the cover assembly may include a plurality of inwardly protruding members separating a continuous surface of the internal cavity from the enclosed electronic device. For example, over a predetermined touch input region of the enclosed device, at least one of the plurality of inwardly protruding members may be configured to be discontinuous. For example, the unitary envelope may be configured to be displaced into contact with the touch input region in response to a touch input.

A number of implementations have been described. Nevertheless, it will be understood that various modifications may be made. For example, advantageous results may be achieved if the steps of the disclosed techniques were performed in a different sequence, or if components of the disclosed systems were combined in a different manner, or if the components were supplemented with other components. Accordingly, other implementations are contemplated within the scope of the following claims.

What is claimed is:

1. A cover assembly for an electronic device, comprising:
a unitary envelope formed from a translucent, radio permissive, and ultraviolet light reflective material, wherein the unitary envelope defines an internal cavity configured to repeatedly receive substantially an entire exposed surface of an enclosed electronic device;
a plurality of inwardly protruding members configured to separate a continuous surface of the internal cavity from the exposed surface of the enclosed electronic device; and,
an insertion aperture, at a distal end of the unitary envelope, defines an elastic opening into the internal cavity, wherein the elastic opening defines a cross-sectional area of a fluid communication channel into the internal cavity such that,
in a stretched state, the cross-sectional area increases to encapsulate the enclosed electronic device within the cover assembly, and,
in a relaxed state, the cross-sectional area decreases to an area smaller than at least one cross-sectional area of the enclosed device such that the elastic opening is configured to be sealingly pressed against the enclosed electronic device forming a seal around the entire elastic opening to form a dust-tight and watertight cover, and,
wherein, when the enclosed electronic device is encapsulated within the unitary envelope, over a predetermined touch input region of the enclosed electronic device, at least one of the plurality of inwardly protruding members is configured to be discontinuous, such that the unitary envelope is configured to be displaced into contact with the touch input region in response to a touch input.

2. The cover assembly of claim 1, wherein when the enclosed electronic device is encapsulated within the unitary envelope, the plurality of inwardly protruding members longitudinally extends from the distal end of the internal cavity towards a proximal surface of the enclosed electronic device, such that a resilience of the unitary envelope against a high-pressure fluid is increased.

3. The cover assembly of claim 1, wherein the insertion aperture is configured to elongate radially by up to 80% to receive the electronic device.

4. The cover assembly of claim 1, wherein the translucent, radio permissive, and ultraviolet light reflective material comprises food-grade silicone.

5. The cover assembly of claim 1, wherein the translucent, radio permissive, and ultraviolet light reflective material comprises a translucent amorphous material.

6. The cover assembly of claim 1, wherein the seal provides protection against an ingress of water up to a pressure of 1450 pounds per square inch, and up to a temperature of 80° C.

7. The cover assembly of claim 1, wherein the enclosed electronic device is a LED indicator.

8. The cover assembly of claim 1, wherein the enclosed electronic device is a capacitive touch input sensor.

9. The cover assembly of claim 1, wherein the enclosed electronic device is a radio transceiver.

10. A cover assembly for an electronic device, comprising:
a unitary envelope formed from a translucent, radio permissive, and ultraviolet light reflective material, wherein the unitary envelope defines an internal cavity configured to repeatedly receive substantially an entire exposed surface of an enclosed electronic device; and,
an insertion aperture, at a distal end of the unitary envelope, defines an elastic opening into the internal cavity, wherein the elastic opening defines a cross-sectional area of a fluid communication channel into the internal cavity such that,
in a stretched state, the cross-sectional area increases to encapsulate the enclosed electronic device within the cover assembly, and,
in a relaxed state, the cross-sectional area decreases to an area smaller than at least one cross-sectional area of the enclosed electronic device such that the elastic opening is configured to be sealingly pressed against the enclosed electronic device forming a seal around the entire elastic opening to form a dust-tight and watertight cover.

11. The cover assembly of claim 1, further comprising
a plurality of inwardly protruding members separating a continuous surface of the internal cavity from the enclosed electronic device, wherein, over a predetermined touch input region of the enclosed device, at least one of the plurality of inwardly protruding members is configured to be discontinuous, such that the unitary envelope is configured to be displaced into contact with the touch input region in response to a touch input.

12. The cover assembly of claim 2, wherein when the enclosed electronic device is encapsulated within the unitary envelope, the plurality of inwardly protruding members longitudinally extends from the distal end of the internal cavity towards a proximal surface of the enclosed electronic device, such that a resilience of the unitary envelope against a high-pressure fluid is increased.

13. The cover assembly of claim 1, wherein the insertion aperture is configured to elongate radially by up to 80% to receive the electronic device.

14. The cover assembly of claim 1, wherein the translucent, radio permissive, and ultraviolet light reflective material comprises food-grade silicone.

15. The cover assembly of claim 1, wherein the translucent, radio permissive, and ultraviolet light reflective material comprises a translucent amorphous material.

16. The cover assembly of claim 1, wherein the seal provides protection against an ingress of water up to a pressure of 1450 pounds per square inch, and up to a temperature of 80° C.

17. The cover assembly of claim 1, wherein the enclosed electronic device comprises a LED indicator.

18. The cover assembly of claim 1, wherein the enclosed electronic device comprises a capacitive touch input sensor.

19. The cover assembly of claim 1, wherein the enclosed electronic device comprises a radio transceiver.

20. A water resistant and ultraviolet light stabilized electronic system comprising:
an electronic device;
a cover assembly configured to encapsulate the electronic device, the cover assembly comprising:
an unitary envelope formed from a translucent, radio permissive, and ultraviolet light reflective material, wherein the unitary envelope defines an internal cavity configured to repeatedly receive substantially an entire exposed surface of the electronic device; and,
an insertion aperture, at a distal end of the unitary envelope, defines an elastic opening into the internal cavity, wherein the elastic opening defines a cross-sectional area of a fluid communication channel into the internal cavity such that,
in a stretched state, the cross-sectional area increases to encapsulate the electronic device within the cover assembly, and,
in a relaxed state, the cross-sectional area decreases to an area smaller than at least one cross-sectional area of the encapsulated electronic device such that the elastic opening is configured to be sealingly pressed against the encapsulated electronic device forming a seal around the entire elastic opening to form a dust-tight and watertight cover such that,
the encapsulated electronic device is configured to operate normally against an ingress of water up to a pressure of 1450 pounds per square inch, and up to a temperature of 80° C.
